(19) United States
(12) Patent Application Publication
(10) Pub. No.: US 2011/0012268 A1
(43) Pub. Date: Jan. 20, 2011

(54) SEMICONDUCTOR DEVICE

(75) Inventors: YASUAKI OZAKI, KANAGAWA (JP); TOORU MASUTOMO, KUMAMOTO (JP); TAKAHIRO MATSUDA, KUMAMOTO (JP); YOSHITAKE TOKUMINE, KANAGAWA (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/826,737

(22) Filed: Jun. 30, 2010

(30) Foreign Application Priority Data
Jul. 14, 2009 (JP) 2009-165447

(51) Int. Cl. H01L 23/48; H01L 21/768

(52) U.S. Cl. 257/774; 438/675; 257/E23.011; 257/E21.577

(57) ABSTRACT

After opening a via hole, the bottom portion and the top portion are rounded by etching performed twice. As a result, resistance of the via hole can be reduced and its quality and life can be enhanced.

### INCORPORATION BY REFERENCE

This Patent Application is based on Japanese Patent Application No. 2009-165447. The disclosure of the Japanese Patent Application is incorporated herein by reference.

### BACKGROUND OF THE INVENTION

1. Field of the Invention

The present invention relates to a semiconductor device and a method of manufacturing thereof. In particular, the present invention relates to a semiconductor device having a via hole and a method of manufacturing thereof.

2. Description of Related Art

A semiconductor device is configured by forming many circuit elements such as transistors, resistors and capacitors on a semiconductor substrate and connecting the elements to one another by interconnections. These elements are formed in a plurality of laminated layers and connected by interconnections through via holes penetrating through the plurality of layers. Therefore, in order to enhance quality of a semiconductor device, it is important to reduce the resistance of the via hole to increase the reliability.

A process flow for forming the via hole on a semiconductor device according to a conventional technique will be described. FIGS. 1A to 1E are sectional views for describing each step of a method of forming a via hole on a semiconductor device according to the conventional technique.

FIG. 1A is a sectional view showing the semiconductor device before the formation of a hole 5. The semiconductor device is formed by laminating a Ti (titanium)/TiN (titanium nitride) film 4, an Al layer 3, a TiN film 2 and an SiO2 layer 1 from the bottom in this order. In other words, the antireflective Ti film 4 or TiN film 2, 4 is formed on each surface of the Al layer 3 to constitute an interconnection layer 10, and the SiO2 layer 1 is formed on the interconnection layer 10.

FIG. 1B is a sectional view for describing a step of forming the hole 5. A portion where the hole 5 is not formed is subjected to PR (Photo Resist) in the state shown in FIG. 1A and then, the hole 5 of a rough profile is formed by dry etching. The hole 5 penetrates the SiO2 layer 1 and the TiN film 2 and reaches the Al layer 3.

FIG. 1C is a sectional view for describing a step of trimming the hole 5. RF (Radio Frequency) etching is performed in the state shown in FIG. 1B to make the angle of the hole 5 at corners on its bottom substantially square.

FIG. 1D is a sectional view for describing a step of forming a barrier metal 6. Ti/TiN sputtering is performed in the state shown in FIG. 1C to form the barrier metal 6 on the inside of the hole 5 and the surface of the SiO2 layer 1.

FIG. 1E is a sectional view for describing a step of forming a plug 7. In the state shown in FIG. 1D, W (tungsten) film is formed on the inside of the hole 5, W is allowed to grow, and then, the W film is subjected to CMP (Chemical Mechanical Polishing) to form the plug 7.

In this concern, in Japanese Patent Application Publication JP-A-Heisei, 6-260440 (referred to as Patent Document 1) discloses an invention relating to a method of manufacturing a semiconductor device.

The method of manufacturing the semiconductor device according to the invention disclosed in Patent Document 1 includes a first step of forming an insulating layer on a silicon substrate, a second step of forming a contact hole in contact with the surface of the silicon substrate in the insulating layer and a third step of etching the surface of the silicon substrate on the bottom of the contact hole by gas including chlorine and fluorine.

According to the disclosure of Patent Document 1, in order to improve coverage of aluminum in the contact hole, a conductive layer is formed on the insulating film to form the contact hole. After that, corners of the conductive layer are removed by argon sputtering and corner filling parts stacked on lower corner parts are formed.

In Japanese Patent Application Publication JP-A-Heisei, 6-295906 (referred to as Patent Document 2) discloses an invention relating to a method of manufacturing a semiconductor device.

In the method of manufacturing the semiconductor device according to the invention disclosed in Patent document 2, a via hole for electrically connecting a lower layer interconnection to an upper layer interconnection, which are provided on a semiconductor substrate across an interlayer insulating film, is formed. The method of manufacturing the semiconductor device includes steps of: forming an interlayer insulating film on the lower layer interconnection; forming a first resist mask having an opening corresponding to the via hole; anisotropically etching the interlayer insulating film by using the first resist mask to form an opening reaching the lower layer interconnection; applying a second resist for filling the opening while leaving the first resist mask and covering the first resist mask; etching back the second resist until the second resist filling the opening has a same height as the interlayer insulating film; tapering an upper portion of a side wall of the opening by tapered reactive ion etching; and stripping the first resist mask and the second resist.

According to the disclosure of Patent Document 2, an upper portion of the via hole is tapered.

Japanese Patent Application Publication JP-P2000-503806A (referred to as Patent Document 3) discloses an invention relating to a method of forming a contact part coated with a conductive material.

The method of forming the contact part coated with the conductive material according to the invention disclosed in Patent Document 3 includes steps of: forming an insulating layer so as to cover an integrated circuit under manufacturing; forming a contact part penetrating the insulating layer to make a lower circuit element exposed; laminating a first conductive layer on the insulating layer; and forming a facet on a lip of the contact part.

According to the disclosure of Patent Document 3, an upper portion of a PSG film is rounded to improve coverage.

### SUMMARY

FIG. 2 is a sectional view for describing a limit of a forming method of a via hole according to a conventional technique. As the aspect ratio of a hole increases, coverage of the barrier metal worsens. In other words, as the depth of the hole relative to the diameter of the hole increases, as shown in FIG. 2, the barrier metal is formed on the bottom portion of the hole more insufficiently.

This is due to the effect of attacking of corrosive gas such as F (fluorine). At growth of via-embedding tungsten, a W film is formed by using WF (tungsten fluoride). As a result, the resistance of aluminum or titanium on the bottom portion of the via hole becomes higher.

Furthermore, as shown in FIG. 1E, there may be the case where the via hole is not completely filled and a space is left in the hole 5. In particular, the top portion 9 may be pointed or the bottom portion 8 may be recessed. Electrostatic focusing can occur at the pointed site. Electrostatic focusing and attacking can occur at the recessed site.

Electrostatic focusing and deterioration due to EM (Electro Migration) can occur at these sites, resulting in decrease in quality and life. According to the art disclosed in Patent Document 3, although the problem of coverage can be solved to some extent, many problems still exist in practicability. Although Patent Documents 1, 2 disclose that the top portion of the contact is tapered or rounded, the bottom portion of the via hole is not adapted at all. In addition, any of Patent Documents 1 to 3 does not describe coverage of the barrier metal.

According to an aspect of the present invention, a semiconductor device includes: an interconnection layer; a silicon oxide layer laminated on the interconnection layer; a via hole penetrating through the silicon oxide layer and reaching to the interconnection layer; a barrier metal covering a whole surface in the via hole; and a plug filled in the via hole. A top portion and a bottom portion of the via hole are rounded by: forming a rough profile of the via hole by dry etching; trimming the via hole by RF (Radio Frequency) etching; and stopping the RF etching by a predetermined timing.

According to another aspect of the present invention, a manufacturing method of a semiconductor device includes: forming an interconnection layer; forming a silicon oxide layer on the interconnection layer; forming a via hole penetrating through the silicon oxide layer and reaching to the interconnection layer; forming a barrier metal covering a whole surface in the via hole; and forming a plug filled in the via hole. The forming the via hole includes: forming a rough profile of the via hole by dry etching; trimming the via hole by RF (Radio Frequency) etching after the forming the rough profile; and stopping the RF etching by a predetermined timing after the trimming.

In a semiconductor device and a method of manufacturing the semiconductor device according to the present invention, after opening a via hole, the bottom portion and the top portion are rounded by etching. As a result, resistance of the via hole is reduced and its quality and life are enhanced.

One reason is that coverage of the barrier metal can be improved by making the top portion and the bottom portion of the via hole rounded. Further, associated with this, it can be prevented from corrosive gas such as F from attacking aluminum on the bottom portion of the via hole or titanium on the interface of aluminum/barrier metal at growth of via-embedding tungsten.

Another reason is that electrostatic focusing on the bottom end portion of the hole can be prevented by making the bottom of the via hole rounded.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is a sectional view for describing a step before formation of a via hole according to a conventional technique;

FIG. 1B is a sectional view for describing a step of forming the via hole by dry etching according to the conventional technique;

FIG. 1C is a sectional view for describing a step of trimming the via hole by RF etching according to the conventional technique;

FIG. 1D is a sectional view for describing a step of forming a barrier metal on the via hole according to the conventional technique;

FIG. 1E is a sectional view for describing a step of forming a plug in the via hole according to the conventional technique;

FIG. 2 is a sectional view for describing a limit of a method of forming a via according to a conventional technique;

FIG. 3A is a sectional view for describing a step before formation of a via hole in an embodiment of the present invention;

FIG. 3B is a sectional view for describing a step of forming the via hole by dry etching in the embodiment of the present invention;

FIG. 3C is a sectional view for describing a step of trimming the via hole by RF etching in the embodiment of the present invention;

FIG. 3D is a sectional view for describing a step of forming a barrier metal on the via hole in the embodiment of the present invention;

FIG. 3E is a sectional view for describing a step of forming a plug in the via hole in the embodiment of the present invention;

FIG. 4 is a graph for comparing chain resistances of the via hole according to a conventional technique and an embodiment of the present invention;

FIG. 5A is a sectional view of a bottom portion of the via hole according to a conventional technique; and

FIG. 5B is a sectional view of a bottom portion of the via hole according to an embodiment of the present invention.

### DESCRIPTION OF THE PREFERRED EMBODIMENTS

A semiconductor device and a method of manufacturing a semiconductor device according to some exemplary embodiments of the present invention will be described below referring to accompanying drawings.

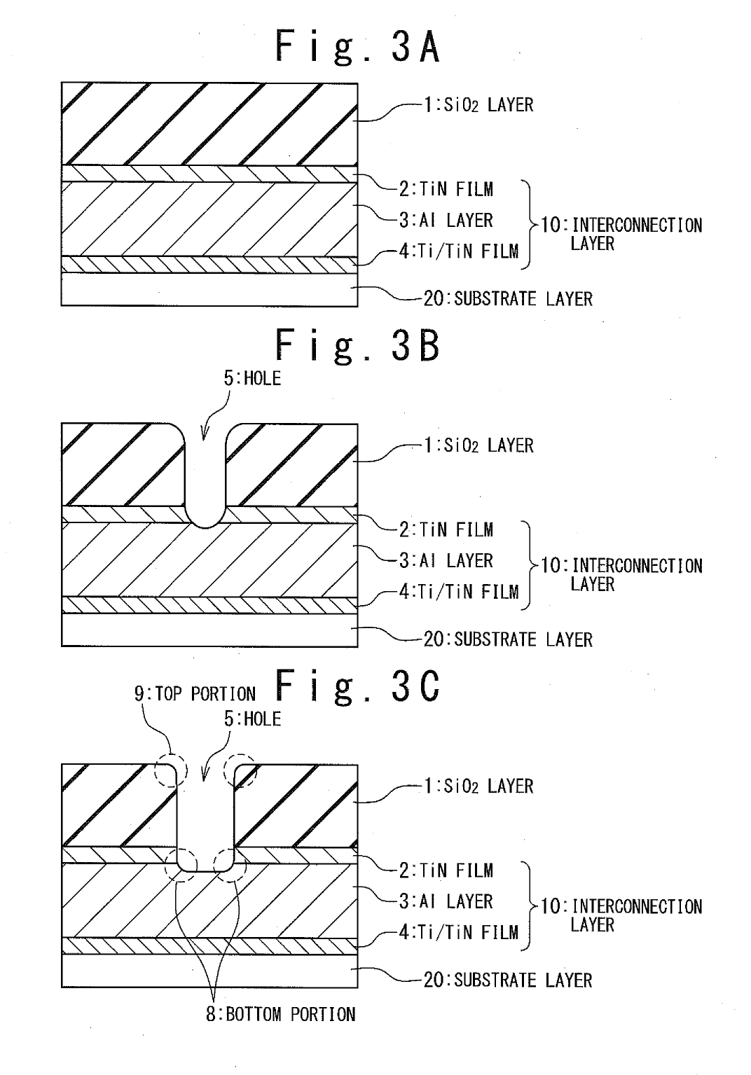

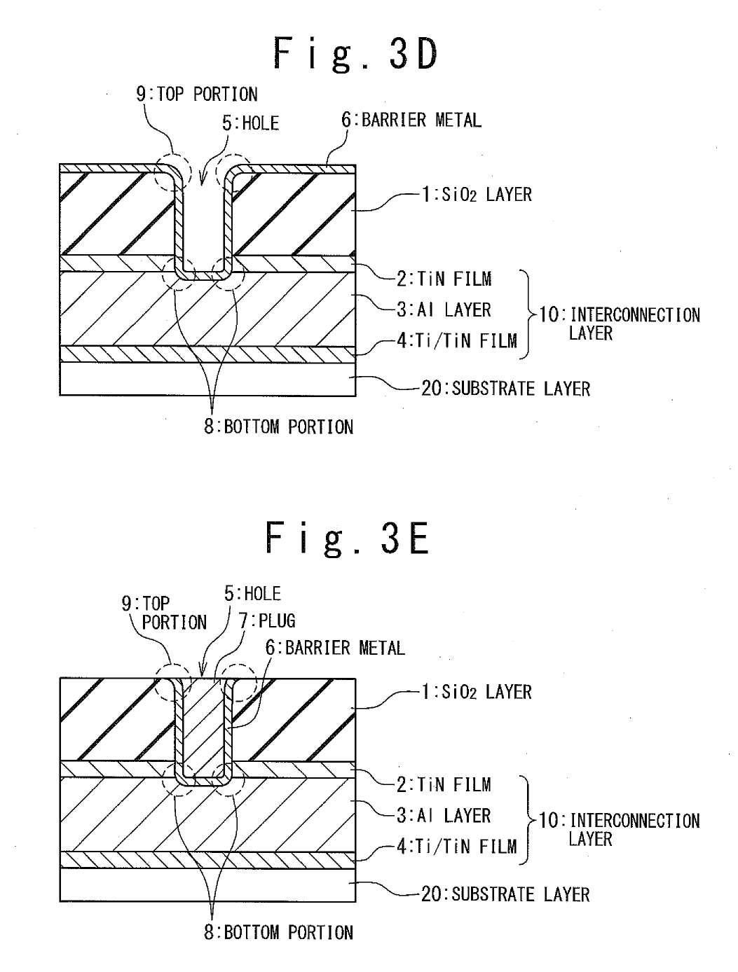

FIG. 3A to FIG. 3E are sectional views for describing steps of a method of forming a via on a semiconductor device in an embodiment of the present invention.

(Step 1)

FIG. 3A is a sectional view of a semiconductor device before formation of the hole 5. The semiconductor device is configured by laminating a Ti/TiN film 4, an Al layer 3, a TiN film 2 and an SiO2 layer 1 from the bottom in this order on, for example, a semiconductor (silicon) substrate layer 20. In other words, the antireflective Ti film 4 or the TiN film 2, 4 is formed on each surface of the Al layer 3 to constitute a laminated layer structure, which is called hereinafter an interconnection layer 10, and the SiO2 layer 1 is formed on the interconnection layer 10.

(Step 2)

FIG. 3B is a sectional view for describing a step of forming the hole 5. The portion where the hole is not formed is subjected to PR in the state shown in FIG. 3A and then, the hole 5 of a rough profile is formed by dry etching. The hole 5 penetrates the SiO2 layer 1 and the TiN film 2 and reaches the Al layer 3. For the steps 1 and 2, the same process to the aforementioned conventional technique can be adopted.

(Step 3)

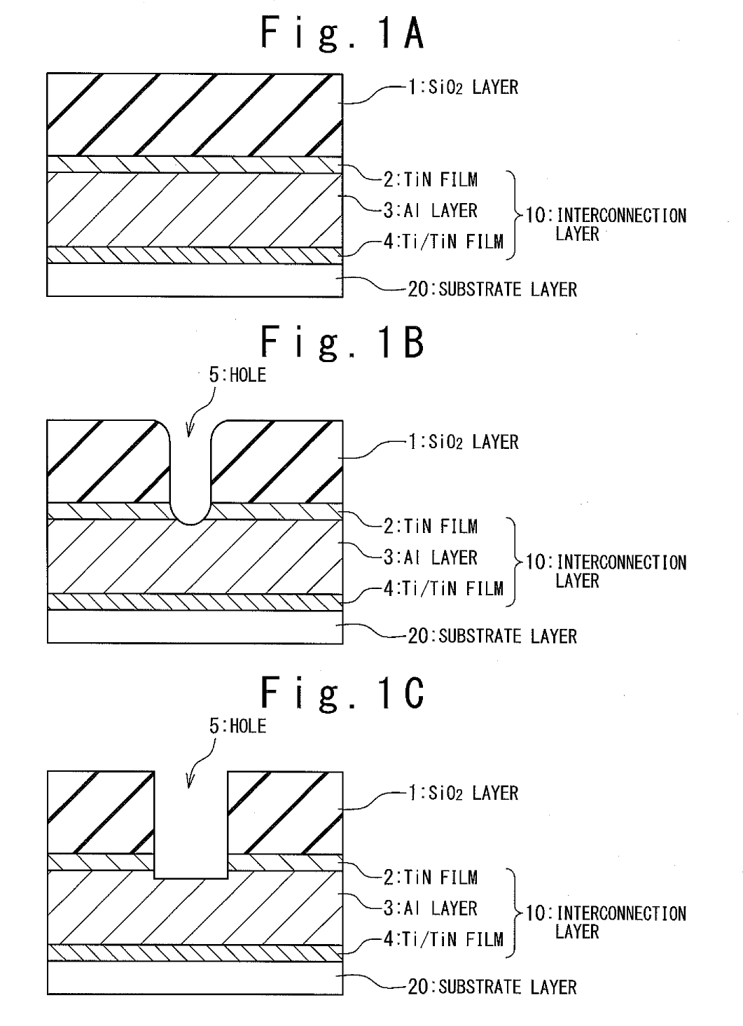

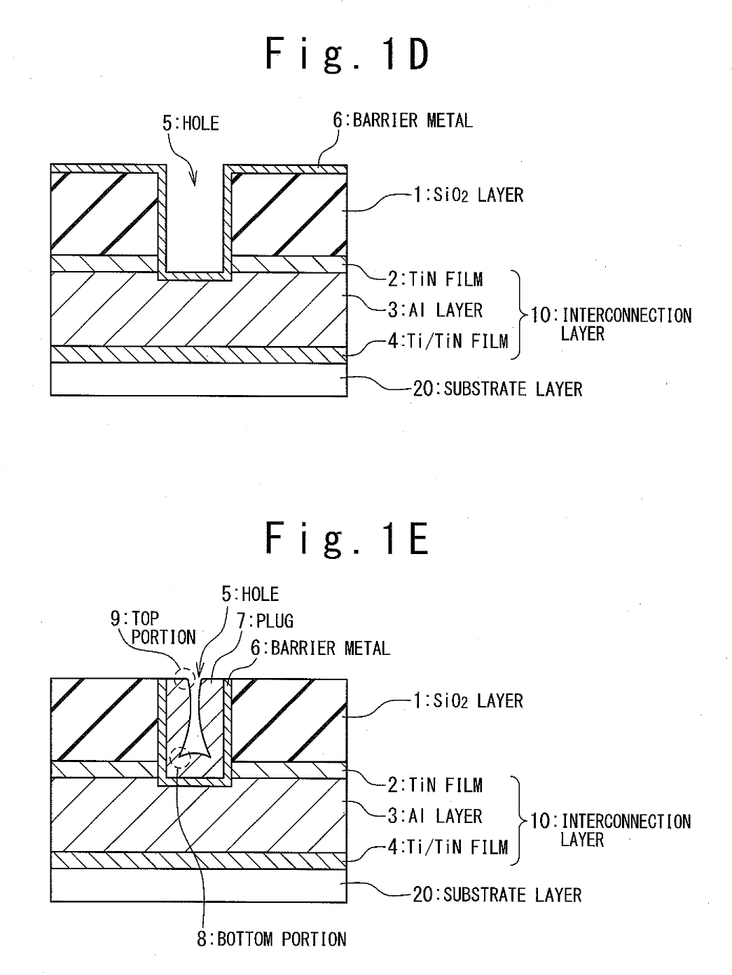

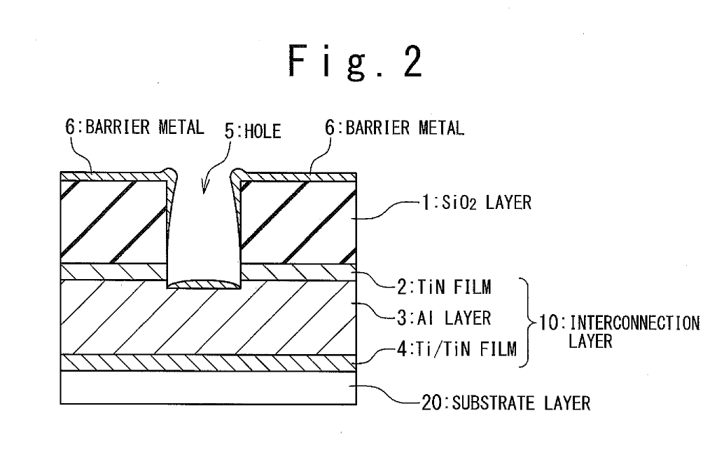

FIG. 3C is a sectional view for describing a step of trimming the via hole 5 so as to make the bottom portion 8 and the top portion 9 of the hole 5 rounded. Here, the term “rounded” means circular, elliptical, spherical or curved shape. RF etching is performed in the state shown in FIG. 3B. At this time, RF etching is performed over a sufficient time until the angle at the bottom portion of the hole 5 becomes the right angle in FIG. 1C according to the conventional technique, while the time for RF etching is reduced according to this embodiment of the present invention. That is, by stopping RF etching between the state shown in FIG. 1B and the state shown in FIG. 1C of the conventional technique, the state shown in

FIG. 3C according to this embodiment can be achieved.

(Step 4)

FIG. 3D is a sectional view for describing a step of forming a barrier metal 6 covering the whole surface in the via hole. Ti/TiN sputtering is performed in the state shown in FIG. 3C to form the barrier metal 6 on the inside of the hole 5 and the surface of the SiO₂ layer 1. At this time, the barrier metal is formed on the inside surface of the hole 5 by sputtering so as to have a thickness of 300 Å

(Angstrom) in the case of Ti and a thickness of 1000 Å in the case of TiN.

(Step 5)

FIG. 3E is a sectional view for describing a step of forming the plug 7. A W film is formed on the inside of the hole 5 in the state shown in FIG. 3D, and W is grown and is further subjected to W CMP to form the plug 7. The plug 7 may be formed by using a W etch back process.

As a result of experiments, it is demonstrated that the resistance value becomes the smallest when the ratio of the rounded section of each of the bottom portion 8 and the top portion 9 to the whole of the plug 7 in the depth direction falls within a range of 5% to 15%. More specifically, this ratio is most preferably approximately 12%.

In the following reference material, a measurement data in a case where the ratio of the rounded section to the whole of the plug 7 in the depth direction is 12% is shown.

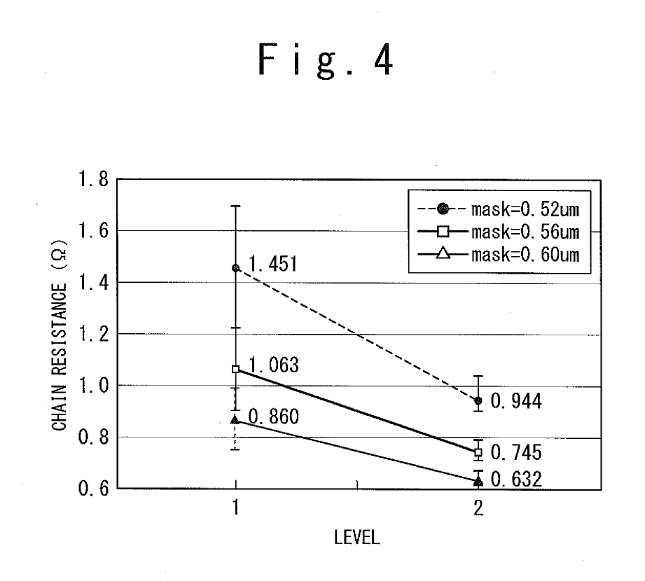

FIG. 4 is a graph for comparing via chain resistances according to a conventional technique and this embodiment of the present invention. Here, the horizontal axis represents level, the first level represents the level according to the conventional technique and the second level represents the level according to this embodiment of the present invention. In this embodiment of the present invention having the second level, the ratio of the rounded section to the whole of the plug 7 in the depth direction is 12%. Three lines correspond to respective mask design values of different via diameters. According to the present embodiment, as compared to the conventional technique, the measured resistance value can be reduced by approximately 27% to 35%.

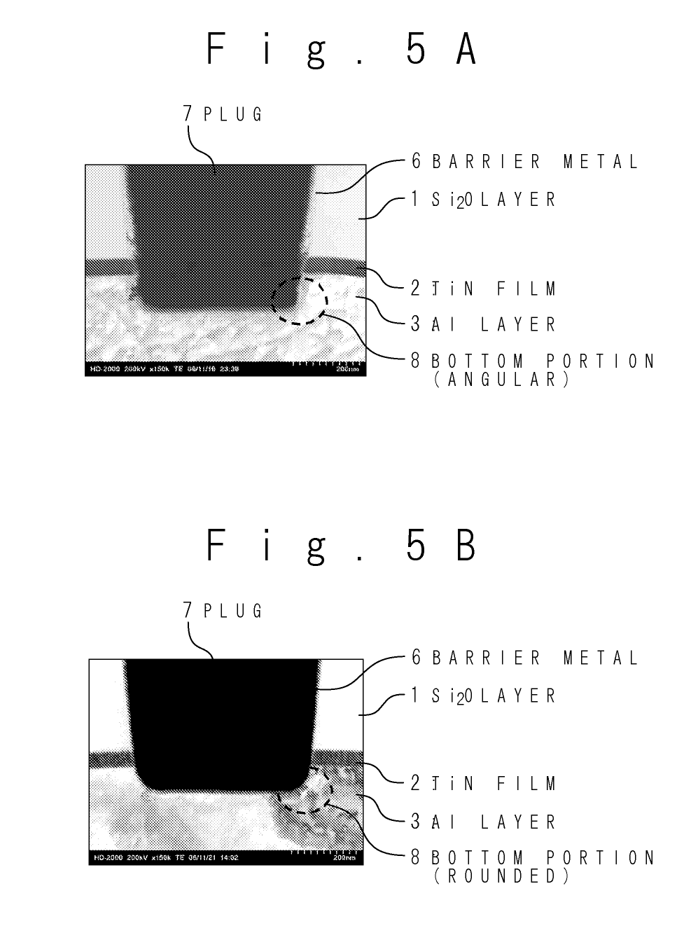

FIG. 5A is a sectional view of a via according to a conventional technique. Noting the inside of the circle expressed by a broken line, the bottom end portion of the via has an angular angle. Here, etching conditions are 1200 W (watts) and 250s (seconds) in the first etching and 1200 W and 60s in the second etching. The thickness of the interlayer oxide film is 750 nm (nanometers) and only a release agent of N311 is used. The thickness of RF etching of barrier metal sputtering is 23 nm.

FIG. 5B is a sectional view of a via in this embodiment of the present invention. Nothing the tip of the arrow, the bottom end portion of the via is rounded. Here, etching conditions are the same as those of the conventional technique except that the thickness of RF etching of barrier metal sputtering is 9 nm.

As described above, in the semiconductor device and the method of manufacturing the semiconductor device according to an embodiment of the present invention, after opening the via hole 5, the bottom portion 8 and the top portion 9 are rounded by etching. As a result, the resistance of the via hole can be reduced and its quality and life can be enhanced.

One reason is that coverage of the barrier metal 6 is improved by making the top portion 8 and the bottom portion 9 of the via hole rounded. As a result, corrosive gas such as F can be prevented from attacking aluminum on the bottom portion of the via hole or titanium on the interface of aluminum/barrier metal at growth of via-embedding tungsten.

Another reason is that electrostatic focusing on the bottom end portion of the hole can be prevented by making the bottom portion of the via hole rounded.

The above-mentioned embodiment is merely an example and each of the specific values may be changed depending on the other parameters.

Although the present invention has been described above in connection with several embodiments thereof, it would be apparent to those skilled in the art that those exemplary embodiments are provided solely for illustrating the present invention, and should not be relied upon to construe the appended claims in a limiting sense.

What is claimed is:

1. A semiconductor device comprising:
an interconnection layer;
a silicon oxide layer laminated on the interconnection layer;
a via hole penetrating through the silicon oxide layer and reaching to the interconnection layer;
a barrier metal covering a whole surface in the via hole; and
a plug filled in the via hole,
wherein a top portion and a bottom portion of the via hole are rounded.

2. The semiconductor device according to claim 1, wherein a size of the top portion and the bottom portion in a direction of a depth of the plug is respectively among 5% to 15% to a depth of the plug.

3. The semiconductor device according to claim 1, wherein a size of the top portion and the bottom portion in a direction of a depth of the plug is respectively approximately 12% to a depth of the plug.

4. The semiconductor device according to claim 1, wherein the interconnection layer comprises:
an aluminum layer; and
a TiN (titanium nitride) film formed on the aluminum layer, and
the barrier metal is formed by Ti/TiN spattering applied to the whole surface in the via hole, and
the plug is formed by a tungsten.

5. A manufacturing method of a semiconductor device comprising:
forming an interconnection layer;
forming a silicon oxide layer on the interconnection layer;
forming a via hole penetrating through the silicon oxide layer and reaching to the interconnection layer;
forming a barrier metal covering a whole surface in the via hole; and
forming a plug filled in the via hole,
wherein the forming the via hole comprises:
forming a rough profile of the via hole by dry etching;
trimming the via hole by RF (Radio Frequency) etching after the forming the rough profile; and
stopping the RF etching by a predetermined timing after the trimming.

6. The manufacturing method of the semiconductor device according to claim 5, wherein a size of the top portion and the bottom portion in a direction of a depth of the plug is respectively among 5% to 15% to a depth of the plug.

7. The manufacturing method of the semiconductor device according to claim 5, wherein a size of the top portion and the bottom portion in a direction of a depth of the plug is respectively approximately 12% to a depth of the plug.

8. The manufacturing method of the semiconductor device according to claim 5, wherein the interconnection layer comprises:
an aluminum layer; and
a TiN (titanium nitride) film formed on the aluminum layer, and
the forming the barrier metal comprises:
forming the barrier metal by Ti/TiN spattering applied to the whole surface in the via hole, and
the forming the plug comprises:
growing a tungsten film on a whole surface of the barrier metal in the via hole; and
applying CMP (Chemical Mechanical Polishing) to the tungsten film after the growing.
